(19) United States
(12) Patent Application Publication
(10) Pub. No.: US 2003/0038566 A1
(43) Pub. Date: Feb. 27, 2003

(54) Disk drive bracket fastening structure

(76) Inventor: Xiao Hua Qiu, Shenzhen (CN)

Correspondence Address: ANDREW C. CHENG, FOXCONN INTERNATIONAL, INC., 458 E. LAMBERT ROAD, FULLERTON, CA, 92835, US

(21) Appl. No.: 09/938,891

(22) Filed: Aug. 24, 2001

(51) Int. Cl. H05K 7/18

(52) U.S. Cl. 312/223.2; 312/111; 312/245; 312/263

(57) ABSTRACT

A disk drive bracket fastening structure includes identical first and second disk drive brackets (30, 30′). She first bracket includes a rack (32) and a cover board (34) secured to the rack. The rack defines a pair of grooves (43) in a bottom panel (36) thereof, and forms a fixing portion (47) between the grooves. The cover board has a pair of rails (53) stamped upwardly therefrom. A fixing tab (55) is formed at a free edge of the cover board between the rails. In assembly the first bracket is firstly secured into a computer enclosure (10). The rails (53′) of the second bracket are then slid into the grooves of the first bracket. The fixing tab (55′) of the second bracket abuts against the fixing portion of the first bracket, and is fastened thereto. The second bracket is thereby firmly secured to the first bracket.

### BACKGROUND OF THE INVENTION

1. Field of the Invention

The present invention relates to fastening of brackets, and more particularly to fastening structures for conveniently fastening disk drive brackets to computer enclosures.

2. Description of Related Art

A personal computer typically comprises data storage devices such as CD-ROM drives, floppy disk drives (FDDs) and hard disk drives (HDDs). These data storage devices are generally fixedly received in brackets within a computer enclosure. A contemporary personal computer comprises a topmost CD-ROM drive bracket, an FDD bracket secured to a bottom of the CD-ROM drive bracket, and an HDD bracket secured to a bottom of the FDD bracket.

Screws are required to directly secure the FDD and HDD brackets into an cenclosure. Fastening or detachment of the screws using a too] is unduly complicated and laborious. This retards installation and removal of the data storage devices.

To streamline such installation and removal, fastening structures have been developed to be interposed between the brackets. The fastening structures secure the brackets in the enclosure, and screws enhance engagement of the brackets. however, shapes of both FDD brackets and HDD brackets vary. Any one fastening structure may fit only one particular FDD bracket being used with one particular HDD bracket. If either a new FDD bracket or a new HDD bracket is needed, then frequently a new fastening structure is also needed. For mass producers, when a new fastening stricture is needed, a new die for forming the new fastening structure is generally required to be made. This results in increased costs.

Examples of fastening structures are found in Taiwan Patent Applications Nos. 83202773 and 87207415.

An improved fastening structure which overcomes the above-mentioned problems is desired.

### SUMMARY OF THE INVENTION

Accordingly, an object of the present invention is to provide a disk drive bracket fastening structure that conveniently fastens a disk drive bracket of a computer enclosure.

Another object of the present invention is to provide a disk drive bracket fastening structure that can be manufactured from a single universal die, thereby reducing costs.

In order to achieve the objects set out above, a disk drive bracket fastening structure of the present invention comprises identical first and second brackets. The first bracket comprises a rack and a cover board secured to the rack. The rack defines a pair of grooves in a bottom panel thereof, and forms a fixing portion between the grooves. The cover board has a pair of rails stamped upwardly therefrom. A fixing tab is formed at a free edge of the cover board between the rails. In assembly, the first bracket is firstly secured into a computer enclosure. The rails of the second bracket are then slid into the grooves of the first bracket. The fixing tab of the second bracket abuts against the fixing portion of the first bracket, and is fastened thereto. The second bracket is thereby firmly secured to the first bracket.

Other objects, advantages and novel features of the present invention will become more apparent from the following detailed description when taken in conjunction with the accompanying drawings.

### BRIEF DESCRIPTION OF THE DRAWINGS

FIG. 1 is an exploded view of a disk drive bracket fastening structure in accordance with a preferred embodiment of the present invention, together with part of a computer enclosure;

FIG. 2 is an exploded view of a disk drive bracket of FIG. 1;

FIG. 3 is an assembled view of FIG. 1:

FIG. 4 is an exploded view of a bracket of a disk drive bracket fastening structure in accordance with an alternative embodiment of the present invention; and

FIG. 5 is an assembled view of a disk drive bracket fastening structure in accordance with the alternative embodiment of the present invention, together with part of a computer enclosure.

### DETAILED DESCRIPTION OF THE INVENTION

Reference will now be made to the drawing figures to describe the embodiments of the present invention in detail.

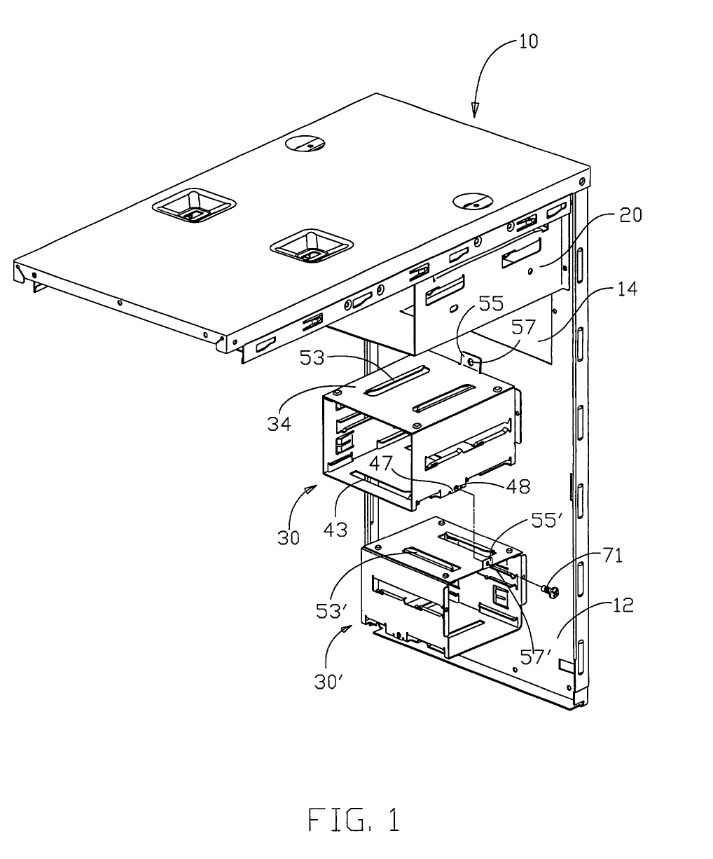

Referring to FIG. 1 a disk drive bracket fastening structure in accordance with a preferred embodiment of the present invention comprises a first disk drive bracket 30 and a second disk drive bracket 30′. A computer enclosure 10 accommodates the first and second brackets 30, 30′ and a CD-ROM drive bracket 20 therein. The enclosure 10 comprises a front wall 12. The front wall 12 defines a first opening (obscured by the CD-ROM drive bracket 20 in FIG. 1) and a second opening 14. The second opening 14 is disposed below the First opening. The CD-ROM drive bracket 20 is secured to the enclosure 10 at the first opening. The first bracket 30 is secured to the enclosure 10 at the second opening 14. The second bracket 30′ is fastened to the first bracket 30 by the fastening structure.

The first and second brackets 30, 30′ are identical in structure. Accordingly, only the first bracket 30 is described in detail herein.

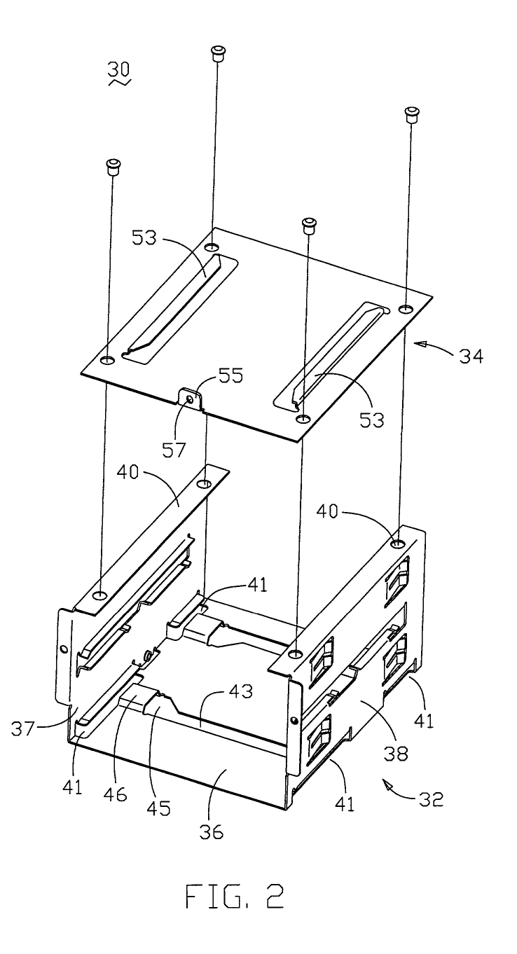

Referring particularly to FIG. 2, the first bracket 30 comprises a rack 32 and a cover board 34. The rack 32 comprises a bottom panel 36, and a pair of parallel side panels 37, 38 extending upwardly from opposite sides of the bottom panel 36 respectively. A flange 40 extends horizontally inwardly from an upper edge of each side panel 37, 38. A pair of aligned notches 41 is defined in. each side panel 37, 38 at a bottom extremity thereof A pair of parallel grooves 43 is defined in the bottom panel 366. Each groove 43 is perpendicular to the side panels 37, 38, and is respectively disposed between directly opposing notches 41 of the side panels 37, 38. A wide portion 45 of each groove 43 is defined proximate to the side panel 37. A width of each wide portion 45 progressively increases toward the side panel 37. A raised portion 46 is formed in the bottom panel 36 between each wide portion 45 and the side panel 37, for facilitating installation of a bracket under the first bracket 30. A fixing portion 47 (see FIG. 1) is formed in the side panel 37 between the notches 41 of the side panel 37. A screw hole 48 (see FIG. 1) is defined in the fixing portion 47.

The cover board 34 is secured to the flanges 40 of the rack 32 with bolts (not labeled). A pair of parallel rails 53 is stamped upwardly from the cover board 34, for slidingly engaging in grooves defined in any bracket above the first bracket 30 that the first bracket 30 may be attached to. The rails 53 are parallel to the side panels 37, 38. Each rail 53 has an L-shaped profile, with respective free edges of the rails 53 facing toward each other. A fixing tab 55 is upwardly formed at an edge of the cover board 34 generally between the rails 53, for abutting against a fixing portion of the said bracket above the first bracket 30 that the first bracket 30 may be attached to. A through hole 57 is defined in the fixing tab 55, and is disposed to align with a screw hole of the said bracket above the first bracket 30 that the first bracket 30 may be attached to.

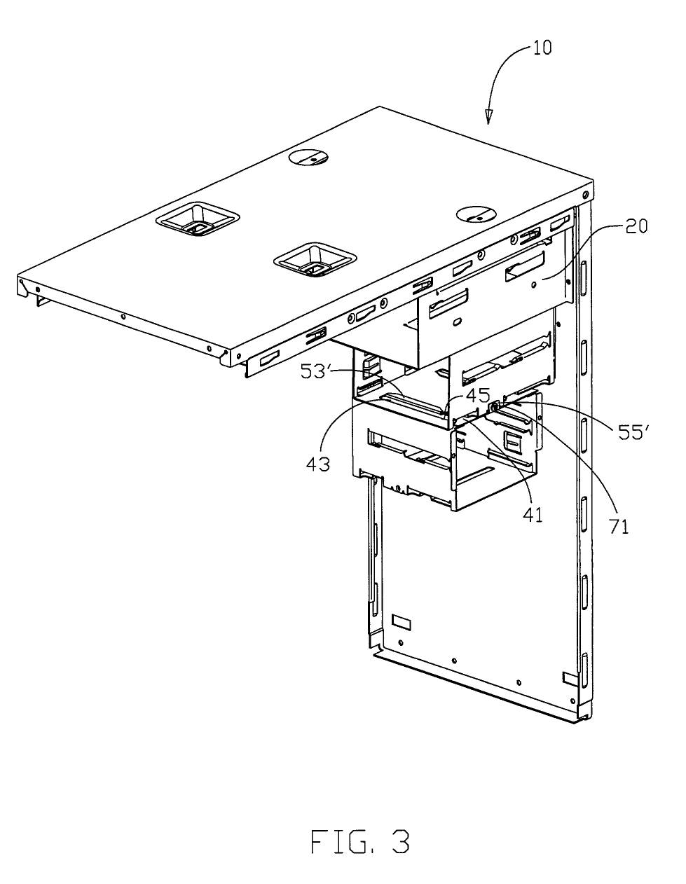

Referring to FIGS. 1 and 3, the second bracket 30′ has rails 53′, a fixing tab 55′, and a through hole 57′.

Referring to FIGS. 1 to 3, in assembly, the first bracket 30 is secured to an inside of the enclosure 10 at the second opening 14. The rails 53′ of the second bracket 30′ are slid into the grooves 43 of the first bracket 30. The fixing tab 55, of the second bracket 30′ abuts against the fixing portion 47 of the first bracket 30. the through hole 57′ of the second bracket 30′ aligns with the screw hole 48 of the first bracket 30. A screw 71 is inserted through the through hole 57′ and engaged in the screw hole 48. Thus, the second bracket 30′ is firmly secured to the first bracket 30.

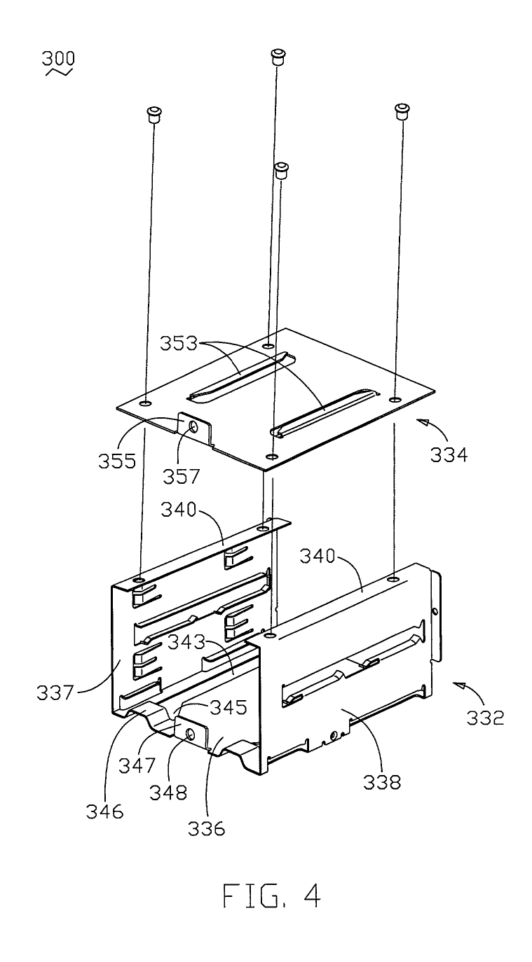

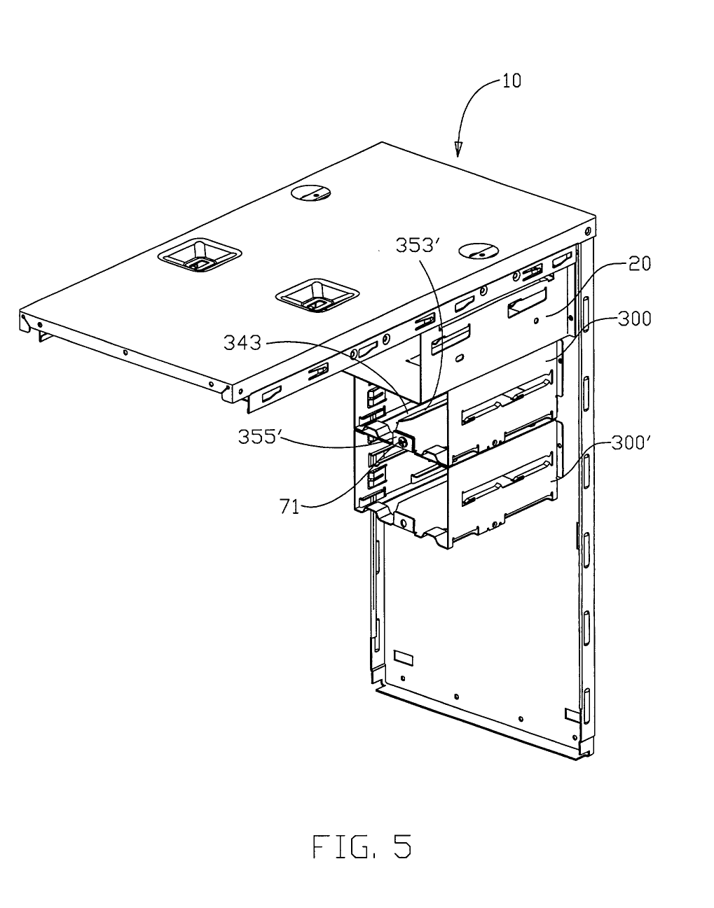

Referring to FIGS. 4 and 5, a disk drive bracket fastening structure in accordance with an alternative embodiment of the present invention comprises a pair of first and second disk drive brackets 300, 300′. The brackets 300, 300′ are identical in structure. Accordingly, only the bracket 300 is described in detail herein.

Referring, particularly to FIG. 4, the first bracket 300 comprises a rack 332 and a cover board 334. The rack 332 comprises a bottom panel 336, and a pair of parallel side panels 337, 338 extending upwardly from opposite sides of the bottom panel 336 respectively. A flange 340 extends horizontally inwardly from an upper edge of each side panel 337, 338. A pair of spaced grooves 343 is defined in the bottom panel 336 proximate to the side panels 337, 338 respectively. The grooves 343 are parallel to the side panels 337, 338. A wide portion 345 of each groove 343 is defined proximate to one end of the bottom panel 336. A width of each wide portion 345 progressively increases toward the said end of the bottom panel 336. A raised portion 346 is formed in the bottom panel 336 between each wide portion 345 and the said end of the bottom panel 336, for facilitating installation of a bracket under the first bracket 300. A fixing portion 347 is upwardly formed from the said end of the bottom panel 336 between the two raised portions 346. A screw hole 348 is defined in the fixing portion 347.

The cover board 334 is secured to the flanges 340 of the rack 332 with bolts (not labeled). A pair of parallel rails 353 is stamped upwardly form the cover hoard 334, for slidingly engaging in grooves defined in any bracket above the first bracket 300 that the first bracket 300 may be attached to. The rails 353 are parallel to the side panels 337, 338. Each rail 353 has an L-shaped profile, with respective free edges of the rails 353 facing toward each other. A fixing tab 355 is upwardly formed at an edge of the cover board 334 generally between the rails 353, for abutting against a fixing portion of the said bracket above the first bracket 300 that the first bracket 300 may be attached to. A through hole 357 is defined in the fixing tab 355, and is disposed to align with a screw hole of the said bracket above the first bracket 300 that the first bracket 300 may be attached to.

Referring to FIGS. 4-5, in assembly, the first bracket 300 is secured to the enclosure 10. The rails 353′ of the second bracket 300′ are slid into the grooves 343 of the first bracket 300. The fixing tab 355′ of the second bracket 300′ abuts against the fixing portion 347 of the first bracket 300. The through hole 357′ of the second bracket 300′ aligns with the screw hole 348 of the first bracket 300. A screw 71 is inserted through the through hole 357′ and engaged in the screw hole 348. Thus, the second bracket 300′ is firmly secured to the first bracket 300.

It is understood that in both above-described embodiments of the present invention, a third bracket may be attached to i underside of the second bracket 30′ (300′). Such attachment would be in similar fashion to attachment of the second bracket 30′ (300′) to the first bracket 30 (300). Similarly, a fourth and subsequent brackets may be attached. Any and all such brackets are easily and securely accommodated in the enclosure 10.

It is to be understood, however. that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A disk drive bracket fastening structure comprising:
at least two identical disk drive brackets, one bracket being firstly secured into an enclosure and each other bracket being successively secured to a bottom of a previously secured bracket, each bracket comprising:
a rack comprising a bottom panel and a pair of side panels extending upwardly from the bottom panel, a pair of grooves being defined in the bottom panel, a fixing portion extending upwardly form an edge of the bottom panel and being located generally between the grooves, and
a cover board secured onto the side panels of the rack, the cover board upwardly forming a pair of rails for slidingly engaging in corresponding grooves of a previously secured bracket, a fixing tab extending upwardly from an edge of the cover board, the fixing tab corresponding to and for engaging with the fixing portion of a previously secured bracket.

2. The disk drive bracket fastening structure in accordance with claim 1. wherein each rail of each cover board has an L-shaped profile.

3. The disk drive bracket fastening structure in accordance with claim 1. wherein each rail of each cover board has a free edge, and the free edges face toward each other.

4. The disk drive bracket fastening structure in accordance with claim 1, wherein a pair of flanges extends inwardly from respective upper portions of the side panels of each bracket, and the corresponding cover board is secured to the flanges.

5. The disk drive bracket fastening structure in accordance with claim 1, wherein the side panels of the rack of each bracket are parallel to each other.

6. The disk drive bracket fastening structure in accordance with claim 5, wherein the rails of each cover board are parallel to the side panels of the corresponding rack.

7. The disk drive bracket fastening structure in accordance with claim 6, wherein the grooves of the bottom panel of each bracket are perpendicular to the side panels.

8. The disk drive bracket fastening structure in accordance with claim 6, wherein the grooves of the bottom panel of each bracket are parallel to the side panels.

9. The disk drive bracket fastening structure in accordance with claim 9, wherein each groove of each bracket has a wide portion proximate to the fixing portion, and a width of each wide portion gradually increases toward the fixing portion.

10. The disk drive bracket fastening structure in accordance with claim 9, wherein a raised portion is formed in the bottom panel of each bracket adjacent each wide portion and proximate to the fixing portion, for facilitating installation of a successive bracket.

11. The disk drive bracket fastening structure in accordance with claim 1, wherein the fixing portion of each bracket defines a screw hole therein, and wherein the Fixing tab of each cover defines a through hole therein adapted for insertion of a screw therethrough.

12. A disk drive bracket fastening structure comprising:
a first disk drive bracket being firstly secured into an enclosure, the first disk drive bracket having a rack, the rack comprising a bottom panel and a pair of side panels extending upwardly from the bottom panel, a pair of grooves being defined in the bottom panel, a fixing portion extending upwardly from an edge of the bottom panel and being located generally between the grooves; and
at least one second disk drive bracket, one second disk drive bracket being firstly secured to the first disk drive bracket and each of any other second disk drive brackets being successively secured to a bottom of a previously secured second disk drive bracket, each second disk drive bracket comprising a rack and a cover board, the rack of each second disk drive bracket being identical to the rack of the first disk drive bracket, the cover board of each second disk drive bracket being secured onto the side panels of the corresponding rack of that second disk drive bracket, the cover board upwardly forming a pair of rails for slidingly engaging in corresponding grooves of a previously secured disk drive bracket, a fixing tab extending upwardly from an edge of the cover board, the fixing tab corresponding to and for engaging with the fixing portion of a previously secured disk drive bracket.

13. The disk drive bracket fastening structure in accordance with claim 12, wherein the rails of each second disk drive bracket are parallel to the grooves of each second disk drive bracket.

14. The disk drive bracket fastening structure in accordance with claim 12, wherein the rails of each second disk drive bracket are perpendicular to the grooves of each second disk drive bracket.
